(19) United States
(12) Patent Application Publication
(10) Pub. No.: US 2019/0363076 A1
(43) Pub. Date: Nov. 28, 2019

(54) ELECTROSTATIC DISCHARGE PROTECTION SEMICONDUCTOR DEVICE

(71) Applicant: Samsung Electronics Co., Ltd., Suwon-si (KR)

(72) Inventor: Jeong Sik Hwang, Suwon-si (KR)

(21) Appl. No.: 16/205,599

(22) Filed: Nov. 30, 2018

(30) Foreign Application Priority Data
May 23, 2018 (KR) 10-2018-0058143

(51) Int. Cl. H01L 27/02; H02H 9/04

(52) U.S. Cl. CPC H01L 27/0248; H02H 9/046

(57) ABSTRACT

A semiconductor device includes a P-type substrate, an N-type well adjacent to a first shallow trench isolation (STI) in the P-type substrate, a first N-type doped region adjacent to the first STI in the N-type well, a second N-type doped region at a boundary between the N-type well and the P-type substrate, a first P-type doped region between the first N-type doped region and the second N-type doped region in the N-type well, a second P-type doped region adjacent to a second STI spaced apart from the first STI in the P-type substrate, a third N-type doped region between the second N-type doped region and the second P-type doped region, and a gate electrode on the P-type substrate between the second N-type doped region and the third N-type doped region.

### CROSS-REFERENCE TO RELATED APPLICATION

Korean Patent Application No. 10-2018-0058143, filed on May 23, 2018, in the Korean Intellectual Property Office, and entitled: “ESD Protection Semiconductor Device,” is incorporated by reference herein in its entirety.

### BACKGROUND

### 1. Field

Embodiments relate to an electrostatic discharge (ESD) protection semiconductor device.

### 2. Description of the Related Art

Electrostatic discharge (ESD) can damage integrated circuit (IC) devices. For example, an IC device can be damaged by accumulated electrostatic charge during the test of the IC device in the manufacturing process, during the assembly of the IC device, or even during the use of a device equipped with the IC device.

### SUMMARY

Embodiments are directed to a semiconductor device, including a P-type substrate, an N-type well adjacent to a first shallow trench isolation (STI) in the P-type substrate, a first N-type doped region adjacent to the first STI in the N-type well, a second N-type doped region at a boundary between the N-type well and the P-type substrate, a first P-type doped region between the first N-type doped region and the second N-type doped region in the N-type well, a second P-type doped region adjacent to a second STI spaced apart from the first STI in the P-type substrate, a third N-type doped region between the second N-type doped region and the second P-type doped region, and a gate electrode on the P-type substrate between the second N-type doped region and the third N-type doped region.

Embodiments are also directed to a semiconductor device, including a first bipolar junction transistor, a second bipolar junction transistor having a base connected to a collector of the first bipolar junction transistor and a collector connected to a base of the first bipolar junction transistor, and a metal oxide semiconductor (MOS) transistor having a gate and a drain connected to the base of the first bipolar junction transistor and a source connected to an emitter of the second bipolar junction transistor.

Embodiments are also directed to a semiconductor device, including a first ESD protection circuit having an anode connected to an I/O terminal for data input/output and a cathode connected to a second voltage terminal, a second ESD protection circuit having an anode connected to a first voltage terminal and a cathode connected to the second voltage terminal, and an ESD protected circuit between the first ESD protection circuit and the second ESD protection circuit. The first ESD protection circuit may include a first MOS transistor having a gate and a drain connected to the I/O terminal, and a source connected to the second voltage terminal, and the second ESD protection circuit may include a second MOS transistor having a gate and a drain connected to the first voltage terminal, and a source connected to the second voltage terminal.

### BRIEF DESCRIPTION OF THE DRAWINGS

Features will become apparent to those of skill in the art by describing in detail example embodiments with reference to the attached drawings in which: FIG. 1 illustrates a circuit diagram of a semiconductor device according to an example embodiment;

FIG. 2 illustrates a cross-sectional view of the semiconductor device according to an example embodiment;

FIG. 3 illustrates a layout diagram of the semiconductor device according to an example embodiment;

FIGS. 4 and 5 illustrate circuit diagrams for explaining the operation of the semiconductor device of FIG. 1;

FIG. 6 illustrates a diagram for explaining the semiconductor device according to an example embodiment;

FIG. 7 illustrates a circuit diagram of a semiconductor device according to an example embodiment; and

FIGS. 8 and 9 illustrate circuit diagrams for explaining the operation of the semiconductor device of FIG. 7.

### DETAILED DESCRIPTION

FIG. 1 illustrates a circuit diagram of a semiconductor device 1 according to an example embodiment.

Referring to FIG. 1, the semiconductor device 1 according to an example embodiment may include a silicon controlled rectifier (SCR)-based circuit. For example, the semiconductor device 1 may include a first bipolar junction transistor BJT1, a second bipolar junction transistor BJT2, and a metal oxide semiconductor (MOS) transistor NM1. The first bipolar junction transistor BJT1 may be, for example, a pnp-type bipolar junction transistor and the second bipolar junction transistor BJT2 may be, for example, an npn-type bipolar junction transistor.

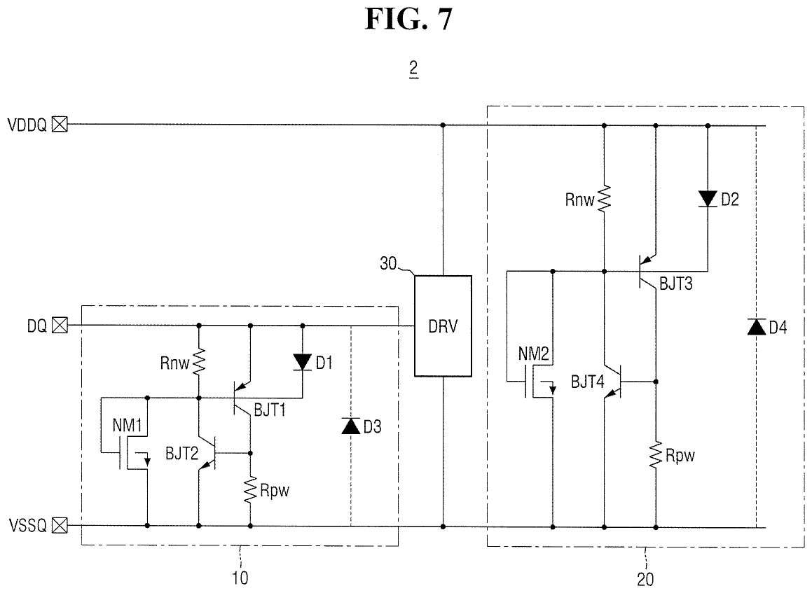

The first bipolar junction transistor BJT1 includes a collector, a base, and an emitter. The emitter of the first bipolar junction transistor BJT1 may be connected to an anode A of the semiconductor device 1. The anode A of the semiconductor device 1 may be connected to, for example, a first voltage terminal VDDQ provided with a power supply voltage, or may be connected to, for example, an input/output (I/O) terminal DQ for data input/output. When the anode A is connected to the I/O terminal DQ, the semiconductor device 1 may be disposed between the I/O terminal DQ and an electrostatic discharge (ESD) protected circuit 30, and the anode A may also be connected to the ESD protected circuit 30. This implementation is shown in FIG. 7.

The base of the first bipolar junction transistor BJT1 may be connected to the anode A through a resistor Rnw. The collector of the first bipolar junction transistor BJT1 may be connected to a cathode C through a resistor Rpw. The cathode C of the semiconductor device 1 may be connected to a second voltage terminal VSSQ provided with a ground voltage. This implementation is shown in FIG. 7.

The second bipolar junction transistor BJT2 includes a collector, a base, and an emitter. The emitter of the second bipolar junction transistor BJT2 may be connected to the cathode C of the semiconductor device 1. The emitter of the second bipolar junction transistor BJT2 may be connected to a source of the MOS transistor NM1.

The base of the second bipolar junction transistor BJT2 may be connected to the cathode C through the resistor Rpw. The collector of the second bipolar junction transistor BJT2 may be connected to the anode A through the resistor Rnw.

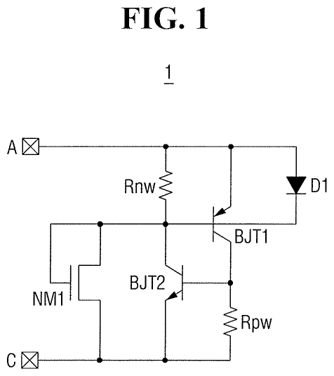

In the present example embodiment, the resistor Rpw may correspond to a parasitic resistor existing in a P-type substrate 100 as illustrated in FIG. 2. The resistor Rnw may correspond to a parasitic resistor existing in an N-type well 110 as illustrated in FIG. 2.

The base of the first bipolar junction transistor BJT1 may be connected to the collector of the second bipolar junction transistor BJT2, and the base of the second bipolar junction transistor BJT2 may be connected to the collector of the first bipolar junction transistor BJT1.

For example, when ESD is applied to the anode A, a reverse voltage is applied to the base and collector of the pnp-type first bipolar junction transistor BJT1. Thus, the first bipolar junction transistor BJT1 is not turned on. However, when the reverse voltage exceeds a predetermined voltage (for example, a breakdown voltage of a pnp-type bipolar junction transistor), the first bipolar junction transistor BJT1 is turned on, and a current starts to flow. Accordingly, the collector current of the first bipolar junction transistor BJT1 is increased.

The increase in the collector current of the first bipolar junction transistor BJT1 leads to an increase in the base current of the npn-type second bipolar junction transistor BJT2. Accordingly, the second bipolar junction transistor BJT2 may be turned on earlier.

When the second bipolar junction transistor BJT2 is turned on and a current flows, the turned-on second bipolar junction transistor BJT2 contributes to an increase in the base current of the first bipolar junction transistor BJT1. Ultimately, the first bipolar junction transistor BJT1 and the second bipolar junction transistor BJT2 are turned on to influence each other, thereby rapidly increasing the current flowing from the anode A to the cathode C. As a result, the ESD protected circuit 30 may be quickly protected from the ESD.

However, if a trigger voltage for turning on the first bipolar transistor BJT1, that is, a breakdown voltage is high enough to exceed a voltage range that can be applied to other circuit elements constituting the ESD protected circuit 30, the circuit elements may be damaged before the first bipolar junction transistor BJT1 is turned on.

The MOS transistor NM1 includes a gate, the source, and a drain. The gate and the drain of the MOS transistor NM1 may be connected to the base of the first bipolar junction transistor BJT1 and the collector of the second bipolar junction transistor BJT2. The source of the MOS transistor NM1 may be connected to the emitter of the second bipolar junction transistor BJT2.

The MOS transistor NM1 contributes to an increase in the base current of the first bipolar junction transistor BJT1, thereby lowering the trigger voltage of the first bipolar junction transistor BJT1. That is, a current flowing through the MOS transistor NM1 amplifies the base current of the first bipolar junction transistor BJT1, causing the first bipolar junction transistor BJT1 to be turned on earlier. Accordingly, the second bipolar junction transistor BJT2 may also be turned on earlier.

The semiconductor device 1 of the present example embodiment further includes a poly-bound diode Dl. The poly-bound diode D1 may be between the emitter and the base of the first bipolar junction transistor BJT1. The poly-bound diode D1 is a diode formed by a first P-type doped region 133 and a second N-type doped region 135 in which no shallow trench isolation (STI) is formed, as illustrated in FIG. 2. The poly-bound diode D1 may also contribute to an increase in the base current of the first bipolar junction transistor BJT1, thereby lowering the trigger voltage of the first bipolar junction transistor BJT1.

FIG. 2 illustrates a cross-sectional view of the semiconductor device 1 according to an example embodiment.

Referring to FIG. 2, the semiconductor device 1 according to the present example embodiment includes the P-type substrate 100, the N-type well 110, a first N-type doped region 131, the first P-type doped region 133, the second N-type doped region 135, a third N-type doped region 137, and a second P-type doped region 139.

The P-type substrate 100 may include the N-type well 110, a first STI 120a, and a second STI 120b spaced apart from the first STI 120a. The N-type well 110 may be formed adjacent to the first STI 120a in the P-type substrate 100.

The first N-type doped region 131 may be formed adjacent to the first STI 120a in the N-type well 110. The second N-type doped region 135 may be formed at a boundary between the N-type well 110 and the P-type substrate 100. The first P-type doped region 133 may be formed between the first N-type doped region 131 and the second N-type doped region 135 in the N-type well 110.

The second P-type doped region 139 may be formed adjacent to the second STI 120b in the P-type substrate 100. The third N-type doped region 137 may be formed between the second N-type doped region 135 and the second P-type doped region 139.

In the present example embodiment, the first P-type doped region 133, the N-type well 110, and the P-type substrate 100 may form the emitter, base, and collector of the first bipolar junction transistor BJT1 of FIG. 1, respectively. The N-type well 110, the P-type substrate 100 and the third N-type doped region 137 may form the emitter, base, and collector of the second bipolar junction transistor BJT2 of FIG. 1, respectively.

The base of the first bipolar junction transistor BJT1 may be connected to the collector of the second bipolar junction transistor BJT2, and the base of the second bipolar junction transistor BJT2 may be connected to the collector of the first bipolar junction transistor BJT1. Thus, as described in connection with FIG. 1, the first and second bipolar junction transistors BJT1 and BJT2 may be turned on to influence each other, thereby rapidly increasing the current flowing from the anode A to the cathode C. Accordingly, the ESD protected circuit 30 may be quickly protected from ESD.

In the present example embodiment, a gate insulating layer 145a and a gate electrode 145b are disposed on the P-type substrate 100 between the second N-type doped region 135 and the third N-type doped region 137. The gate electrode 145b may include, for example, polysilicon or metal. The second N-type doped region 135, the third N-type doped region 137, and the gate structure of the gate insulating layer 145a and the gate electrode 145b may form the MOS transistor NM1 of FIG. 1. The gate and the drain of the MOS transistor NM1 may be connected to each other, and the gate electrode 145b may be connected to the second N-type doped region 135 in the present example embodiment.

As described in connection with FIG. 1, the MOS transistor NM1 contributes to an increase in the base current of the first bipolar junction transistor BJT1, thereby lowering the trigger voltage of the first bipolar junction transistor BJT1.

In the present example embodiment, an STI is not formed between the first P-type doped region 133 and the second N-type doped region 135. Thus, the first P-type doped region 133 and the second N-type doped region 135 may form the poly-bound diode D1 of FIG. 1.

The poly-bound diode D1 may also contribute to an increase in the base current of the first bipolar junction transistor BJT1, thereby lowering the trigger voltage of the first bipolar junction transistor BJT1.

Further, in the present example embodiment, no STI is formed between the first N-type doped region 131 and the first P-type doped region 133 as well as between the third N-type doped region 137 and the second P-type doped region 139. If an STI is formed between doped regions, the current flow between the doped regions is limited. Therefore, the STI is not formed to promote the current flow and, by extension, reduce on-resistance Ron.

Rather than form an STI, a first dummy gate electrode 141b, a second dummy gate electrode 143b, and a third dummy gate electrode 147b may be formed. In addition, a first dummy gate insulating layer 141a, a second dummy gate insulating layer 143a and a third dummy gate insulating layer 147a may be formed under the first dummy gate electrode 141b, the second dummy gate electrode 143b and the third dummy gate electrode 147b, respectively.

The first dummy gate electrode 141b may be formed on the N-type well 110 between the first N-type doped region 131 and the first P-type doped region 133. The second dummy gate electrode 143b may be formed on the N-type well 110 between the first P-type doped region 133 and the second N-type doped region 135, and the third dummy gate electrode 147b may be formed on the P-type substrate 100 between the third N-type doped region 137 and the second P-type doped region 139.

In the present example embodiment, the first N-type doped region 131, the first P-type doped region 133, the first dummy gate electrode 141b, and the second dummy gate electrode 143b may be connected to the anode A of the semiconductor device 1. The third N-type doped region 137, the second P-type doped region 139, and the third dummy gate electrode 147b may be connected to the cathode C of the semiconductor device 1.

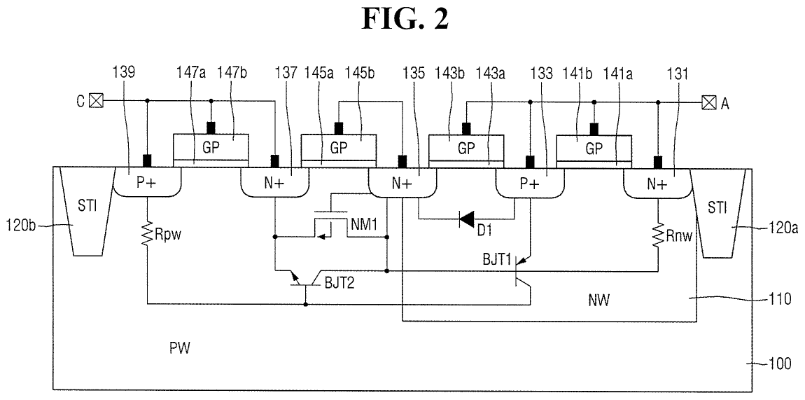

FIG. 3 illustrates a layout diagram of the semiconductor device 1 according to an example embodiment.

Referring to FIG. 3, in the layout of the semiconductor device 1 according to the present example embodiment, the first dummy gate electrode 141b is disposed between the first N-type doped region 131 and the first P-type doped region 133. The second dummy gate electrode 143b is disposed between the first P-type doped region 133 and the second N-type doped region 135, and the third dummy gate electrode 147b is disposed between the third N-type doped region 137 and the second P-type doped region 139. By disposing the dummy gate electrodes 141b, 143b, and 147b between the doped regions, automatic placement of an STI in regions that are not defined in the layout of the semiconductor device 1 may be prevented. That is, the dummy gate electrodes 141b, 143b, and 147b may be placed at the layout stage to prevent the formation of an STI between the doped regions.

The gate electrode 145b is disposed between the second N-type doped region 135 and the third N-type doped region 137 to form the MOS transistor NM1 of FIG. 1.

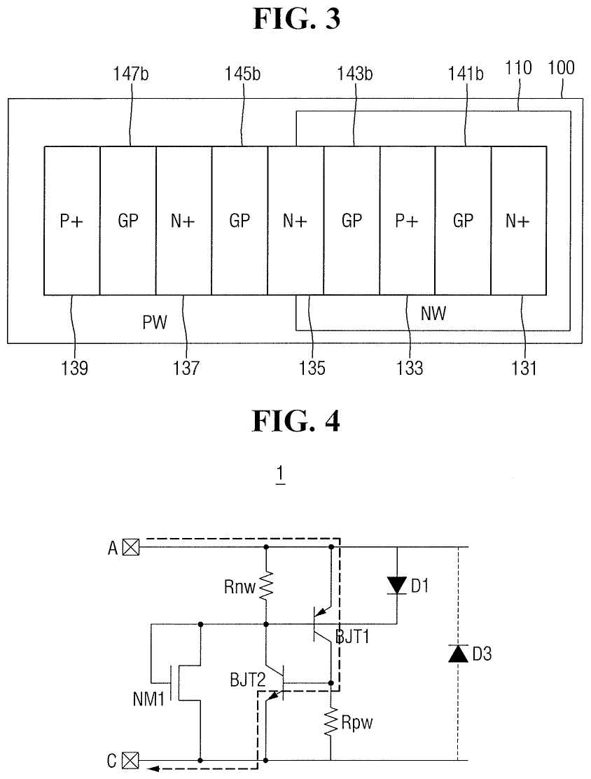

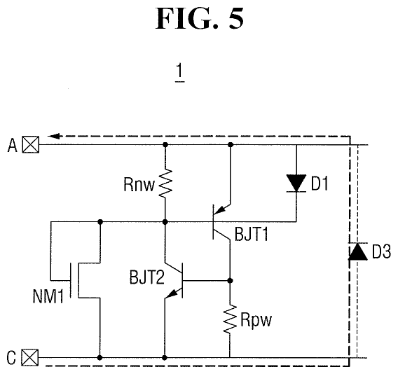

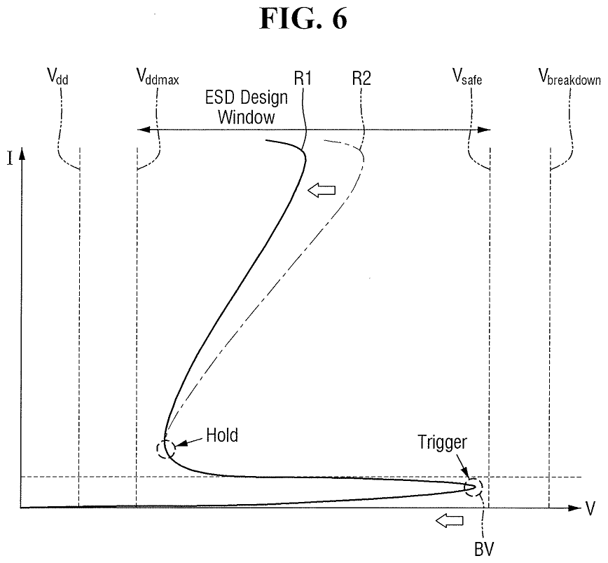

FIGS. 4 and 5 illustrate circuit diagrams for explaining the operation of the semiconductor device 1 according to an example embodiment of FIG. 1, and FIG. 6 illustrates a diagram for explaining the semiconductor device 1 according to an example embodiment and advantageous effects brought about by the operation of the semiconductor device 1.

Referring to FIG. 4, a dotted arrow indicates the flow of current when positive ESD is applied to the anode A of the semiconductor device 1 according to an example embodiment of FIG. 1.

When positive ESD is applied to the anode A, a current flows toward the cathode C through the first bipolar junction transistor BJT1 and the second bipolar junction transistor BJT2.

When a reverse voltage applied to the base and collector of the pnp-type first bipolar junction transistor BJT1 exceeds a predetermined voltage (for example, a breakdown voltage of a pnp-type bipolar junction transistor), the first bipolar junction transistor BJT1 is turned on, and a current starts to flow. Accordingly, the collector current of the first bipolar junction transistor BJT1 is increased.

The increase in the collector current of the first bipolar junction transistor BJT1 leads to an increase in the base current of the npn-type second bipolar junction transistor BJT2. Accordingly, the second bipolar junction transistor BJT2 may be turned on earlier.

When the second bipolar junction transistor BJT2 is turned on and a current flows, the turned-on second bipolar junction transistor BJT2 contributes to an increase in the base current of the first bipolar junction transistor BJT1. Further, the MOS transistor NM1 and the poly-bound diode Dl also contribute to the increase in the base current of the first bipolar junction transistor BJT1. Thus, the current driving ability is improved, and the ESD protected circuit 30 may be quickly protected from the ESD.

Referring to FIG. 5, a dotted arrow indicates the flow of current when negative ESD is applied to the cathode C of the semiconductor device 1 according to an example embodiment of FIG. 1.

When negative ESD is applied to the cathode C, the current flows toward the anode A through a parasitic diode D3 formed by the P-type substrate 100 and the N-type well 110 as illustrated in FIG. 2.

At this time, the first bipolar junction transistor BJT1 and the second bipolar junction transistor BJT2 are not turned on.

Referring to FIG. 6, the semiconductor device 1 according to an example embodiment may help lower the trigger voltage of the first bipolar junction transistor BJT1 and lower the on-resistance Ron.

Referring first to a portion indicated by BV in FIG. 6, when the trigger voltage for turning on the first bipolar junction transistor BJT1, that is, the breakdown voltage, is high enough to exceed the voltage range that can be applied to, e.g., other circuit elements constituting the ESD protected circuit 30, the circuit elements may be damaged before the first bipolar junction transistor BJT1 is turned on.

However, the semiconductor device 1 of the present example embodiment is structured such that the first bipolar junction transistor BJT1 is turned on earlier by using the MOS transistor NM1 and the poly-bound diode D1, which may contribute to an increase in the base current of the first bipolar junction transistor BJT1, thereby lowering the trigger voltage of the first bipolar junction transistor BJT1. Further, the second bipolar junction transistor BJT2 is also turned on earlier to improve the current driving capability.

Next, referring to portions indicated by R1 and R2 in FIG. 6, the on-resistance Ron of a bipolar junction transistor may be greater in an environment where process conditions for manufacturing an SCR-based circuit are adapted to process conditions for manufacturing a complementary metal oxide semiconductor (CMOS). That is, R1 indicates a case where the process conditions for manufacturing an SCR-based circuit conform to process conditions for manufacturing a bipolar junction transistor, and R2 indicates a case where the process conditions for manufacturing an SCR-based circuit conform to the process conditions for manufacturing a CMOS.

In the semiconductor device 1 of the present example embodiment, since an STI formed between doped regions limits the current flow between the doped regions, the STI may not be formed between the doped regions to promote the current flow and, by extension, lower the on-resistance Ron.

FIG. 7 illustrates a circuit diagram of a semiconductor device 2 according to an example embodiment.

Referring to FIG. 7, the semiconductor device 2 according to an example embodiment includes a first ESD protection circuit 10, a second ESD protection circuit 20, and an ESD protected circuit 30.

In the present example embodiment, the first ESD protection circuit 10 has an anode connected to an I/O terminal DQ for data input/output and a cathode connected to a second voltage terminal VSSQ.

The first ESD protection circuit 10 includes a first bipolar junction transistor BJT1, and includes a second bipolar junction transistor BJT2 having a base connected to a collector of the first bipolar junction transistor BJT1 and a collector connected to a base of the first bipolar junction transistor BJT1. An emitter of the first bipolar junction transistor BJT1 is connected to the I/O terminal DQ, and an emitter of the second bipolar junction transistor BJT2 is connected to the second voltage terminal VSSQ.

The first ESD protection circuit 10 further includes a first MOS transistor NM1 having a gate and a drain connected to the I/O terminal DQ, and a source connected to the second voltage terminal VSSQ.

The first ESD protection circuit 10 further includes a first poly-bound diode D1 formed between the emitter and the base of the first bipolar junction transistor BJT1.

The second ESD protection circuit 20 has an anode connected to a first voltage terminal VDDQ and a cathode connected to the second voltage terminal VSSQ.

The second ESD protection circuit 20 includes a third bipolar junction transistor BJT3, and includes a fourth bipolar junction transistor BJT4 having a base connected to a collector of the third bipolar junction transistor BJT3 and a collector connected to a base of the third bipolar junction transistor BJT3. An emitter of the third bipolar junction transistor BJT3 is connected to the first bipolar junction transistor BJT1, and an emitter of the fourth bipolar junction transistor BJT4 is connected to the second voltage terminal VSSQ.

The second ESD protection circuit 20 further includes a second MOS transistor NM2 having a gate and a drain connected to the first voltage terminal VDDQ and a source connected to the second voltage terminal VS SQ.

The second ESD protection circuit 20 further includes a second poly-bound diode D2 formed between the emitter and the base of the third bipolar junction transistor BJT3.

The ESD protected circuit 30 is disposed between the first ESD protection circuit 10 and the second ESD protection circuit 20.

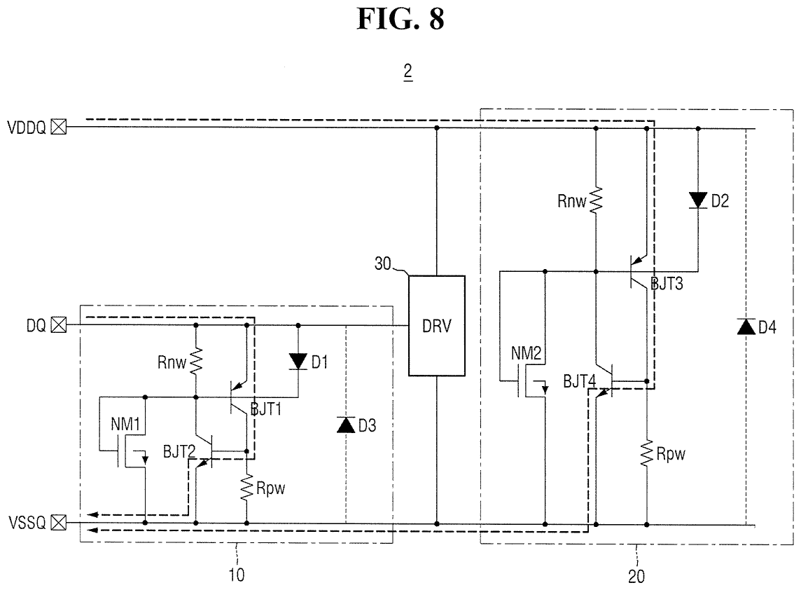

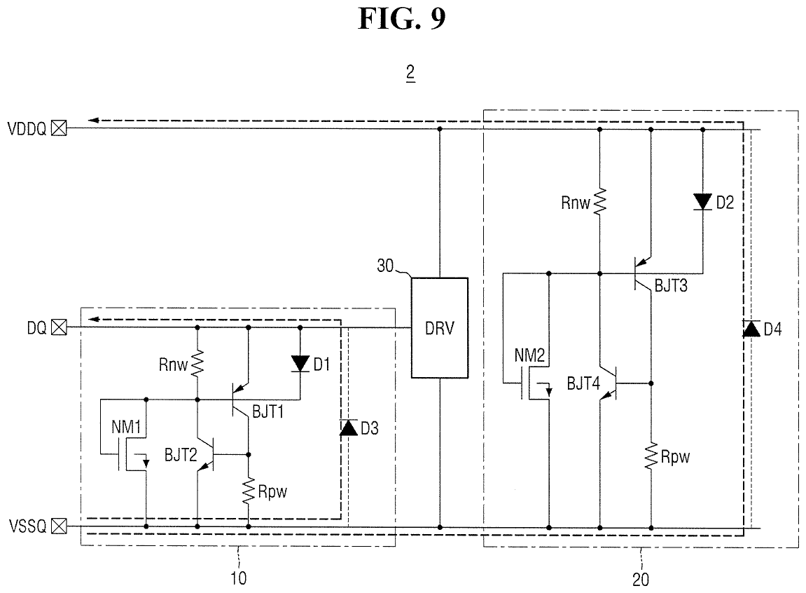

FIGS. 8 and 9 illustrate circuit diagrams for explaining the operation of the semiconductor device 2 according to an example embodiment of FIG. 7.

Referring to FIG. 8, dotted arrows indicate the flow of current when positive ESD is applied to an anode A of the semiconductor device 2 according to an example embodiment of FIG. 7.

In the first ESD protection circuit 10, when positive ESD is applied to the I/O terminal DQ, a current flows to the second voltage terminal VSSQ through the first bipolar junction transistor BJT1 and the second bipolar junction transistor BJT2.

When a reverse voltage applied to the base and collector of the pnp-type first bipolar junction transistor BJT1 exceeds a predetermined voltage (for example, a breakdown voltage of a pnp-type bipolar junction transistor), the first bipolar junction transistor BJT1 is turned on, and a current starts to flow. Accordingly, the collector current of the first bipolar junction transistor BJT1 is increased.

The increase in the collector current of the first bipolar junction transistor BJT1 leads to an increase in the base current of the npn-type second bipolar junction transistor BJT2. Accordingly, the second bipolar junction transistor BJT2 may be turned on earlier.

When the second bipolar junction transistor BJT2 is turned on and a current flows, the turned-on second bipolar junction transistor BJT2 contributes to an increase in the base current of the first bipolar junction transistor BJT1. Further, the first MOS transistor NM1 and the first poly-bound diode D1 also contribute to the increase in the base current of the first bipolar junction transistor BJT1. Thus, the current driving ability is improved, and the ESD protected circuit 30 may be quickly protected from the ESD.

In the second ESD protection circuit 20, when the positive ESD is applied to the first voltage terminal VDDQ, a current flows to the second voltage terminal VSSQ through the third bipolar junction transistor BJT3 and the fourth bipolar junction transistor BJT4.

When a reverse voltage applied to the base and collector of the pnp-type third bipolar junction transistor BJT3 exceeds a predetermined voltage (for example, a breakdown voltage of a pnp-type bipolar junction transistor), the third bipolar junction transistor BJT3 is turned on, and a current starts to flow. Accordingly, the collector current of the third bipolar junction transistor BJT3 is increased.

The increase in the collector current of the third bipolar junction transistor BJT3 leads to an increase in the base current of the npn-type fourth bipolar junction transistor BJT4. Accordingly, the fourth bipolar junction transistor BJT4 may be turned on earlier.

When the fourth bipolar junction transistor BJT4 is turned on and a current flows, the turned-on fourth bipolar junction transistor BJT4 contributes to an increase in the base current of the third bipolar junction transistor BJT3. Further, the second MOS transistor NM2 and the second poly-bound diode D2 also contribute to the increase in the base current of the third bipolar junction transistor BJT3. Thus, the current driving ability is improved, and the ESD protected circuit 30 may be quickly protected from the ESD.

In FIG. 9, dotted arrows indicate the flow of current when negative ESD is applied to a cathode C of the semiconductor device 2 according to an example embodiment of FIG. 7.

Referring to FIG. 9, in the first ESD protection circuit 10, when negative ESD is applied to the second voltage terminal VSSQ, the current flows to the I/O terminal DQ through a parasitic diode D3 formed by the P-type substrate 100 and the N-type well 110 as illustrated in FIG. 2. At this time, the first bipolar junction transistor BJT1 and the second bipolar junction transistor BJT2 are not turned on.

In the second ESD protection circuit 20, when negative ESD is applied to the second voltage terminal VSSQ, the current flows to the first voltage terminal VDDQ through a parasitic diode D4 formed by the P-type substrate 100 and the N-type well 110 as illustrated in FIG. 2. At this time, the third bipolar junction transistor BJT3 and the fourth bipolar junction transistor BJT4 are not turned on.

By way of summation and review, to protect an IC device from ESD, a technique using a silicon controlled rectifier (SCR) may be utilized. In this case, however, a high trigger voltage and an on-resistance (Ron) may pose limitations. Further, an ESD protection scheme should accommodate IC devices that are increasingly operating at higher speeds and improve the current driving capability.

As described above, the first bipolar junction transistor BJT1 may be turned on earlier by using the MOS transistor NM1 and the poly-bound diode D1 to contribute to an increase in the base current of the first bipolar junction transistor, thereby lowering the trigger voltage of the first bipolar junction transistor BJT1. Further, the second bipolar junction transistor BJT2 may also be turned on earlier to improve the current driving capability.

In addition, an STI formed between doped regions may limit the current flow between the doped regions. Thus, the STI may not be formed between the doped regions, thus promoting current flow and, by extension, lowering the on-resistance Ron.

Embodiments may provide an electrostatic discharge (ESD) semiconductor device that may reduce a high trigger voltage and on-resistance and provide superior current driving capability in an ESD protection technique using a silicon controlled rectifier (SCR).

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a P-type substrate;
an N-type well adjacent to a first shallow trench isolation (STI) in the P-type substrate;
a first N-type doped region adjacent to the first STI in the N-type well;
a second N-type doped region at a boundary between the N-type well and the P-type substrate;
a first P-type doped region between the first N-type doped region and the second N-type doped region in the N-type well;
a second P-type doped region adjacent to a second STI spaced apart from the first STI in the P-type substrate;
a third N-type doped region between the second N-type doped region and the second P-type doped region; and
a gate electrode on the P-type substrate between the second N-type doped region and the third N-type doped region.

2. The semiconductor device as claimed in claim 1, wherein:
no STI is between the first N-type doped region and the first P-type doped region,
no STI is between the first P-type doped region and the second N-type doped region, and
no STI is between the third N-type doped region and the second P-type doped region.

3. The semiconductor device as claimed in claim 1, wherein:
no STI is between the first P-type doped region and the second N-type doped region, and
the first P-type doped region and the second N-type doped region form a poly-bound diode.

4. The semiconductor device as claimed in claim 1, further comprising:
a first dummy gate electrode on the N-type well between the first N-type doped region and the first P-type doped region;
a second dummy gate electrode on the N-type well between the first P-type doped region and the second N-type doped region; and
a third dummy gate electrode on the P-type substrate between the third N-type doped region and the second P-type doped region.

5. The semiconductor device as claimed in claim 4, wherein the first N-type doped region, the first P-type doped region, the first dummy gate electrode, and the second dummy gate electrode are connected to an anode of the semiconductor device.

6. The semiconductor device as claimed in claim 4, wherein the third N-type doped region, the second P-type doped region, and the third dummy gate electrode are connected to a cathode of the semiconductor device.

7. The semiconductor device as claimed in claim 1, wherein the gate electrode is connected to the second N-type doped region.

8. The semiconductor device as claimed in claim 1, wherein the first P-type doped region, the N-type well, and the P-type substrate form an emitter, a base, and a collector of a first bipolar junction transistor, respectively.

9. The semiconductor device as claimed in claim 1, wherein the N-type well, the P-type substrate, and the third N-type doped region form an emitter, a base, and a collector of a second bipolar junction transistor, respectively.

10. A semiconductor device, comprising:
a first bipolar junction transistor;
a second bipolar junction transistor having a base connected to a collector of the first bipolar junction transistor and a collector connected to a base of the first bipolar junction transistor; and
a metal oxide semiconductor (MOS) transistor having a gate and a drain connected to the base of the first bipolar junction transistor and a source connected to an emitter of the second bipolar junction transistor.

11. The semiconductor device as claimed in claim 10, further comprising a poly-bound diode between an emitter and the base of the first bipolar junction transistor.

12. The semiconductor device as claimed in claim 10, wherein:
the emitter of the first bipolar junction transistor is connected to an anode of the semiconductor device, and
the emitter of the second bipolar junction transistor is connected to a cathode of the semiconductor device.

13. The semiconductor device as claimed in claim 12, wherein:
the semiconductor device is connected between an input/output (I/O) terminal for data input/output and an electrostatic discharge (ESD) protected circuit, and
the I/O terminal and the ESD protected circuit are connected to the anode.

14. A semiconductor device, comprising:
a first ESD protection circuit having an anode connected to an I/O terminal for data input/output and a cathode connected to a second voltage terminal;
a second ESD protection circuit having an anode connected to a first voltage terminal and a cathode connected to the second voltage terminal; and
an ESD protected circuit between the first ESD protection circuit and the second ESD protection circuit, wherein:
the first ESD protection circuit includes a first MOS transistor having a gate and a drain connected to the I/O terminal, and a source connected to the second voltage terminal, and
the second ESD protection circuit includes a second MOS transistor having a gate and a drain connected to the first voltage terminal, and a source connected to the second voltage terminal.

15. The semiconductor device as claimed in claim 14, wherein the first ESD protection circuit further includes:
a first bipolar junction transistor, and
a second bipolar junction transistor having a base connected to a collector of the first bipolar junction transistor and a collector connected to a base of the first bipolar junction transistor.

16. The semiconductor device as claimed in claim 15, wherein the first ESD protection circuit further includes a first poly-bound diode between an emitter and the base of the first bipolar junction transistor.

17. The semiconductor device as claimed in claim 16, wherein:
the emitter of the first bipolar junction transistor is connected to the I/O terminal, and
an emitter of the second bipolar junction transistor is connected to the second voltage terminal.

18. The semiconductor device as claimed in claim 14, wherein the second ESD protection circuit further includes:
a third bipolar junction transistor, and
a fourth bipolar junction transistor having a base connected to a collector of the third bipolar junction transistor and a collector connected to a base of the third bipolar junction transistor.

19. The semiconductor device as claimed in claim 18, wherein the second ESD protection circuit further includes a second poly-bound diode between an emitter and the base of the third bipolar junction transistor.

20. The semiconductor device as claimed in claim 19, wherein:
the emitter of the third bipolar junction transistor is connected to the first bipolar junction transistor, and
an emitter of the fourth bipolar junction transistor is connected to the second voltage terminal.
